(19) United States
(12) Patent Application Publication
(10) Pub. No.: US 2025/0218806 A1
(43) Pub. Date: Jul. 3, 2025

(54) APPARATUS FOR PROCESSING SUBSTRATE

(71) Applicant: SEMES CO., LTD., Cheonan-si (KR)

(72) Inventors: Do Hyeon YOON, Cheonan-si (KR); Eun Seok KIM, Cheonan-si (KR); Mi So PARK, Cheonan-si (KR)

(73) Assignee: SEMES CO., LTD., Cheonan-si (KR)

(21) Appl. No.: 18/983,506

(22) Filed: Dec. 17, 2024

(30) Foreign Application Priority Data
Dec. 27, 2023 (KR) 10-2023-0192454

(51) Int. Cl. H01L 21/67

(52) U.S. Cl. CPC H01L 21/67028

(57) ABSTRACT

Disclosed is an apparatus for treating a substrate, the apparatus including: a housing providing a processing space; a support unit for supporting a substrate in the processing space; a first supply port for supplying a processing fluid into the processing space; an exhaust port for exhausting the processing fluid within the processing space; and a porous member disposed to face the first supply port within the processing space, and having pores.

### CROSS-REFERENCE TO RELATED APPLICATIONS

This application claims priority to and the benefit of Korean Patent Application No. 10-2023-0192454 filed in the Korean Intellectual Property Office on Dec. 27, 2023, the entire contents of which are incorporated herein by reference.

### TECHNICAL FIELD

The present invention relates to an apparatus for processing a substrate, and more particularly, to an apparatus for processing a substrate by using a processing fluid.

### BACKGROUND ART

To manufacture semiconductor devices, a desired pattern is formed on a substrate through various processes, such as photography, etching, ashing, ion implantation, and thin film deposition. Each process uses a variety of processing liquids, and contaminants and particles may be generated during the process. To address this, cleaning processes are essential before and after each process to remove contaminants and particles.

Typically, the cleaning process is accomplished by treating the substrate with chemicals and rinse solutions followed by drying. In recent years, organic solvents, such as isopropyl alcohol (IPA), have been used as rinse solutions, and drying is performed using supercritical fluids.

On the other hand, when the drying processing is performed, a processing fluid may be supplied to the area below a filler. When a pressure difference between a pressure of a supplied processing fluid and a pressure inside a chamber is large during the supply of the processing fluid, turbulence may be formed in the edge region of the substrate. Due to the formation of such turbulence, the IPA liquid layer on the top surface of the substrate may be directly affected by the processing fluid. In this case, the drying or pushing of the IPA liquid layer by the processing fluid may cause the top head of the substrate pattern to be exposed.

### SUMMARY OF THE INVENTION

The present invention has been made in an effort to provide a substrate treating apparatus capable of efficiently treating a substrate.

The present invention has also been made in an effort to provide a substrate treating apparatus capable of minimizing turbulence formed at an edge of a wafer by the supply of a processing fluid when performing a supercritical process.

The present invention has also been made in an effort to provide a substrate treating apparatus capable of minimizing turbulence formed at an edge of a wafer when supplying a processing fluid.

The object of the present invention is not limited thereto, and other objects not mentioned will be clearly understood by those of ordinary skill in the art from the following description.

An exemplary embodiment of the present invention provides an apparatus for treating a substrate, the apparatus including: a housing providing a processing space; a support unit for supporting a substrate in the processing space; a first supply port for supplying a processing fluid into the processing space; an exhaust port for exhausting the processing fluid within the processing space; and a porous member disposed to face the first supply port within the processing space, and having pores.

In the exemplary embodiment, the porous member may be provided in a porous material.

In the exemplary embodiment, the porous member may be provided below the substrate supported on the support unit.

In the exemplary embodiment, a buffer groove may be formed in a bottom wall of the housing, and the porous member may be disposed within the buffer groove.

In the exemplary embodiment, when viewed from above, the porous member may be provided with the same area as the buffer groove.

In the exemplary embodiment, the porous member may be provided to be in contact with a bottom surface of surfaces defining the buffer groove.

In the exemplary embodiment, the bottom wall may be further formed with a center groove extending from the buffer groove and positioned below the buffer groove, and the first supply port may be provided on a bottom surface of surfaces forming the center groove.

In the exemplary embodiment, the porous member may be provided only in the buffer groove between the buffer groove and the center groove.

In the exemplary embodiment, the porous member may be spaced apart from the bottom wall at a position higher than the bottom wall.

In the exemplary embodiment, a filler member may be provided between the porous member and the substrate supported on the support unit.

In the exemplary embodiment, the porous member and the filler member may be disposed opposite each other.

In the exemplary embodiment, when viewed from above, the filler member may be provided with a larger area than the porous member.

In the exemplary embodiment, the apparatus may further include a second supply port formed above the substrate supported on the support unit, and for supplying a processing fluid to the processing space.

Another exemplary embodiment of the present invention provides an apparatus for treating a substrate, the apparatus including: a housing providing a processing space; a support unit for supporting a substrate in the processing space; a supply port for supplying a processing fluid into the processing space; an exhaust port for exhausting the processing fluid within the processing space; and a porous member disposed to face the supply port and the exhaust port within the processing space, and having pores, in which the porous member includes: a plate part having a plate shape; a first leg part extending downwardly from the plate part and being in contact with the supply port; and a second leg part extending downwardly from the plate part and being in contact with the exhaust port.

In the exemplary embodiment, the first leg part and the second leg part may have a cylindrical shape.

In the exemplary embodiment, when viewed from above, the first leg part may be provided with a wider area than an outlet of the supply port, and the second leg part may be provided with an area wider than an inlet of the exhaust port.

Still another exemplary embodiment of the present invention provides an apparatus for treating a substrate, the apparatus including: a housing providing a processing space; a support unit for supporting a substrate in the processing space; a first supply port for supplying a processing fluid into the processing space; an exhaust port for exhausting the processing fluid within the processing space; a second supply port formed above the substrate supported on the support unit, and for supplying a processing fluid to the processing space; a buffer groove formed in a bottom wall of the housing; a porous member disposed within the buffer groove; and a filler member provided between the porous member and the substrate supported on the support unit, and the porous member is provided from a porous material.

In the exemplary embodiment, the porous member may be provided below the substrate supported on the support unit, and the porous member may be provided with the same area as the buffer groove when viewed from above, and the porous member may be provided to be in contact with a lower surface of surfaces defining the buffer groove.

In the exemplary embodiment, the bottom wall may be further formed with a center groove extending from the buffer groove and positioned below the buffer groove, and the first supply port may be provided on a bottom surface of surfaces forming the center groove, and the porous member may be provided only in the buffer groove between the buffer groove and the center groove.

In the exemplary embodiment, the porous member may include: a plate part having a plate shape; a first leg part extending downwardly from the plate part and being in contact with the supply port; and a first leg part extending downwardly from the plate part and being in contact with the supply port; and the first leg part and the second leg part have a cylindrical shape, when viewed from above, the first leg part may be provided with a wider area than an outlet of the supply port, and the second leg part may be provided with an area wider than an inlet of the exhaust port.

According to the exemplary embodiment of the present invention, it is possible to efficiently process the substrate.

According to the exemplary embodiment of the invention, by providing the porous material adjacent to the supply port, turbulence formed at the edge of the wafer by the supply of processing fluid during supercritical processes may be minimized.

The effect of the present invention is not limited to the foregoing effects, and the not-mentioned effects will be clearly understood by those skilled in the art from the present specification and the accompanying drawings.

### BRIEF DESCRIPTION OF THE DRAWINGS

Various features and advantages of the non-limiting exemplary embodiments of the present FIG. 1 is a top plan view schematically illustrating a substrate treating system according to an exemplary embodiment of the present invention.

FIG. 2 is a to plan view schematically illustrating a liquid treating chamber provided in a substrate treating apparatus according to an exemplary embodiment of the present invention.

FIG. 3 is a top plan view schematically illustrating a first exemplary embodiment of a drying chamber provided in a substrate treating apparatus according to the exemplary embodiment of the present invention.

FIG. 4 is a perspective view schematically illustrating a porous member according to the exemplary embodiment of the present invention.

FIG. 5 is a diagram schematically illustrating a flow of a processing fluid when a processing fluid is supplied to a drying chamber according to the exemplary embodiment of the present invention.

FIG. 6 is a top plan view schematically illustrating a second exemplary embodiment of a drying chamber provided in a substrate treating apparatus according to the exemplary embodiment of the present invention.

FIG. 7 is a top plan view schematically illustrating a third exemplary embodiment of a drying chamber provided in a substrate treating apparatus according to the exemplary embodiment of the present invention.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

The term “and/or” may include any one and one or more combinations of enumerated items. Further, in the present specification, “connected” means not only when member A and member B are directly connected, but also when member A and member B are indirectly connected by interposing member C between member A and member B.

Exemplary embodiments of the invention may be modified in many ways, and the scope of the invention should not be construed as being limited to the exemplary embodiments below. These embodiments are provided to more fully illustrate the invention to one of average skill in the art. Therefore, the shapes of elements in the drawings are exaggerated to emphasize clearer descriptions.

FIG. 1 is a top plan view schematically illustrating a substrate treating system according to an exemplary embodiment of the present invention.

Referring to FIG. 1, a substrate treating system may include an index module 10, a treating module 20, and a control module 30. According to the exemplary embodiment, the index module 10 and the treating module 20 may be disposed in one direction. Hereinafter, a direction along which the index module 10 and the treating module 20 are disposed may be referred to as a first direction 92, a direction perpendicular to the first direction 92 when viewed from above may be referred to as a second direction 94, and a direction perpendicular to both the first direction 92 and the second direction 94 may be referred to as a third direction 96.

The index module 10 may transfer a substrate W from a container 80 in which the substrate W is stored to the treating module 20, and may accommodate the substrate W that has been processed in the treating module 20 to the container 80. A longitudinal direction of the index module 10 may be provided in the second direction 94. The index module 10 may have a load port 12 and an index frame 14 (index frame). With respect to the index frame 14, the load port 12 may be positioned on an opposite side of the treating module 20. The container 80 containing the substrates W may be placed on the load port 12. A plurality of load ports 12 may be provided, and the plurality of load ports 12 may be disposed along the second direction 94.

As the container 80, an airtight container, such as a Front Open Unified Pod (FOUP), may be used. The container 80 may be placed on the load port 12 by a transfer means (not illustrated), such as an overhead transfer, an overhead conveyor, or an automatic guided vehicle, or an operator.

The index frame 14 may be provided with an index robot 120. Within the index frame 14, a guide rail 140 may be provided with a longitudinal direction in the second direction 94, and the index robot 120 may be movably provided on the guide rail 140. The index robot 120 may include a hand 122 on which the substrate W is placed, and the hand 122 may be movably provided for forward and backward movement, rotatable with respect to the third direction 96 as an axis, and movably provided along the third direction 96. A plurality of hands 122 may be provided spaced apart in an up and down direction, and the hands 122 may be capable of forward and backward movement independently of each other.

The treating module 20 may include a buffer unit 200, a transfer unit 300, a liquid treating chamber 400, and a drying chamber 500. The buffer unit 200 may provide a space for the substrate W being loaded into the treating module 20 and for the substrate W being unloaded from the treating module 20 to temporarily stay. The liquid treating chamber 400 may perform a liquid processing process by supplying a liquid onto the substrate W to liquid-process the substrate W. The drying chamber 500 may perform a drying process to remove any remaining liquid on the substrate W. The transfer chamber 300 may transfer the substrate W between the buffer unit 220, the liquid treating chamber, and the drying chamber 500.

The transfer device 300 may be provided with a longitudinal direction thereof in the first direction 92. The buffer unit 200 may be disposed between the index module 10 and the transfer device 300. The liquid treating chamber 400 and the drying chamber 500 may be disposed at a lateral portion of the transfer device 300. The liquid treating chamber 400 and the transfer device 300 may be disposed along the second direction 94. The drying chamber 500 and the transfer device 300 may be disposed along the second direction 94. The buffer unit 200 may be positioned at one end of the transport device 300.

According to the exemplary embodiment, the liquid treating chambers 400 are disposed on opposite sides of the transfer device 300 and the drying chambers 500 are disposed on opposite sides of the transfer device 300, and the liquid treating chambers 400 may be disposed closer to the buffer unit 200 than the drying chambers 500. At one side of the transfer device 300, the liquid treating chambers 400 may be provided in an arrangement of A×B (each of A and B is 1 or a natural larger than 1) in the first direction 92 and the third direction 96. Further, at one side of the transfer device 300, the drying chambers 500 may be provided in number of C× D (each of C and D is 1 or a natural number larger than 1) in the first direction 92 and the third direction 96. As described above, one side of the transfer device 300 may be provided with only liquid treating chambers 400 and the other side may be provided with only drying chambers 500.

The transfer device 300 may have a transfer robot 320. Within the transfer device 300, a guide rail 340 of which a longitudinal direction is provided in the first direction 92 may be provided, and the transfer robot 320 may be movably provided on the guide rail 340. The transfer robot 320 includes a hand 322 on which the substrate W is placed, and the hand 322 may be movably provided for forward and backward movement, rotatable with respect to the third direction 96 as an axis, and movably provided along the third direction 96. The plurality of hands 322 is provided while being spaced apart from each other in the vertical direction, and is capable of independently moving forwardly and backwardly.

The buffer unit 200 may include a plurality of buffers 220 in which the substrate W is placed. The buffers 220 may be arranged to be spaced apart from each other along the third direction 96. A front face and a rear face of the buffer unit 200 may be opened. The front face may be a face facing the index module 10, and the rear face may be a face facing the transfer device 300. The index robot 120 may approach the buffer unit 200 through the front face, and the transfer robot 320 may approach the buffer unit 200 through the rear face.

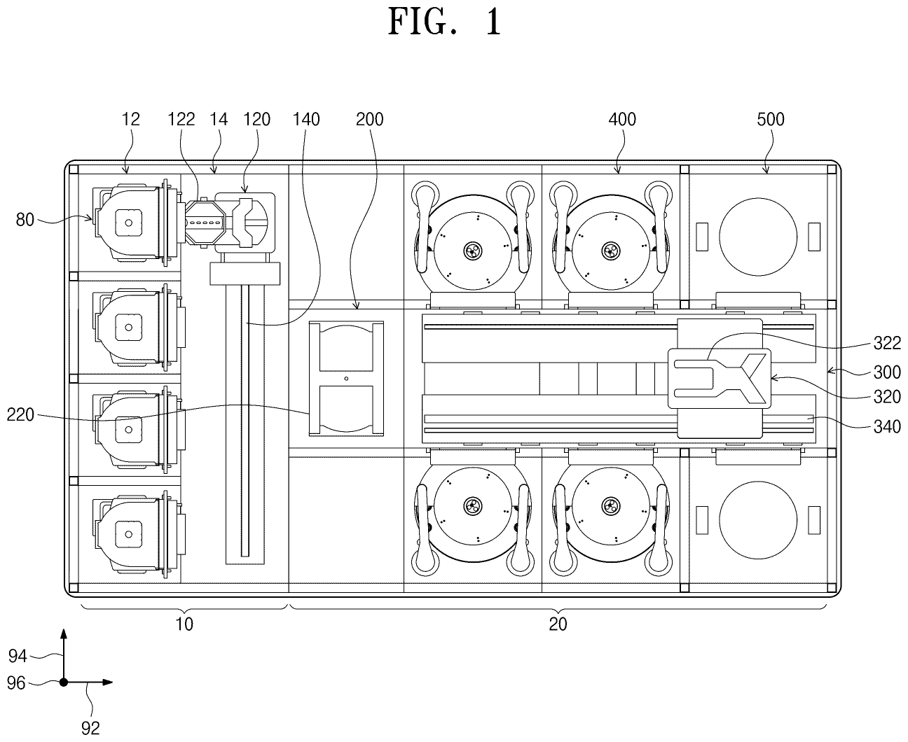

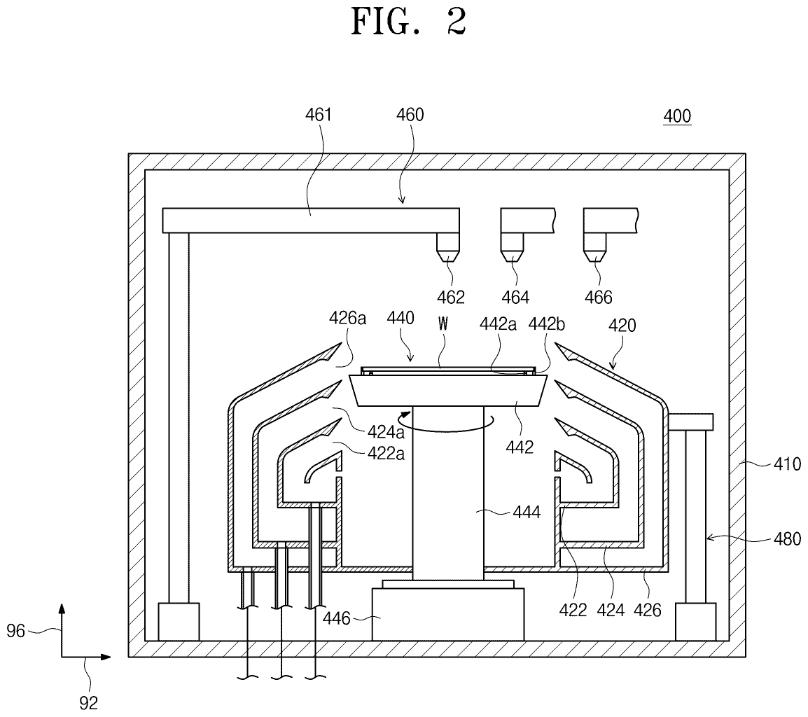

FIG. 2 is a to plan view schematically illustrating a liquid treating chamber provided in the substrate treating apparatus according to the exemplary embodiment of the present invention.

Referring to FIG. 2, the liquid treating chamber 400 may have a housing 410, a cup 420, a support unit 440, a liquid supply unit 460, and a lifting unit 480. The housing 410 may be provided in a generally cuboidal shape. The cup 420, the support unit 440, and the liquid supply unit 460 may be disposed within the housing 410.

The cup 420 may have a processing space with an open top, and the substrate W may be liquidized within the processing space. The support unit 440 may support the substrate W in the processing space 102. The liquid supply unit 460 may supply a liquid onto the substrate W supported on the support unit 440. The liquid may be provided in a plurality of types, and may be sequentially supplied onto the substrate W. The lifting unit 480 may adjust the relative height between the cup 420 and the support unit 440.

According to the exemplary embodiment, the cup 420 may have a plurality of recovery containers 422, 424, and 426. The recovery containers 422, 424, and 426 may each have a recovery space for recovering a liquid used to process the substrate. Each of the recovery containers 422, 424, and 426 may be provided in the shape of a ring that surrounds the support unit 440. As the liquid processing process proceeds, the pre-processing liquid that is scattered by the rotation of the substrate W may be introduced into the recovery space through inlets 422a, 424a, and 426a of the recovery containers 422, 424, and 426, respectively. According to the exemplary embodiment, the cup 420 may include a first reservoir 422, a second reservoir 424, and a third reservoir 426. The first recovery container 422 may be disposed to surround the support unit 440, the second recovery container 424 may be disposed to surround the first recovery container 422, and the third recovery container 426 may be disposed to surround the second recovery container 424. A second inlet 424a, which introduces the liquid into the second recovery container 424, may be positioned above a first inlet 422a, which introduces the liquid into the first recovery container 422, and a third inlet 426a, which introduces the liquid into the third recovery container 426, may be positioned above the second inlet 424a.

The support unit 440 may have a support plate 442 and a drive shaft 444. An upper surface of the support plate 442 may be provided in a generally circular shape, and may have a diameter larger than a diameter of the substrate W. A center portion of the support plate 442 may be provided with a support pin 442a to support a rear surface of the substrate W, and the support pin 442a may be provided with a top end thereof protruding from the support plate 442 such that the substrate W is spaced a certain distance from the support plate 442. A chuck pin 442b may be provided at an edge portion of the support plate 442. The chuck pin 442b is provided to protrude upwardly from the support plate 442, and may support the lateral portion of the substrate W so that the substrate W is not separated from the support unit 440 when the substrate W is rotated. The drive shaft 444 is driven by the driver 446 and is connected to the center of the bottom surface of the substrate W, and may rotate the support plate 442 about its center axis.

According to the exemplary embodiment, the liquid supply unit 460 may include a first nozzle 462, a second nozzle 464, and a third nozzle 466. The first nozzle 462 may supply a first liquid onto the substrate W. The first liquid may be a liquid that removes any residual film or foreign substances on the substrate W. The second nozzle 464 may supply a second liquid onto the substrate W. The second liquid may be a liquid that is more soluble in a third liquid. For example, the second liquid may be more soluble in the third liquid than the first liquid. The second liquid may be a liquid that neutralizes the first liquid supplied onto the substrate W. Further, the second liquid may be a liquid that neutralizes the first liquid and at the same time is more soluble in the third liquid than the first liquid. According to the exemplary embodiment, the second liquid may be water. The third nozzle 466 may supply the third liquid onto the substrate W. The third liquid may be a liquid that is highly soluble in the processing fluid used in the drying chamber 500. For example, the third liquid may be a liquid that is more soluble in the processing fluid used in the drying chamber 500 than the second liquid. According to the exemplary embodiment, the third liquid may be an organic solvent. The organic solvent may be isopropyl alcohol (IPA). In addition to isopropyl alcohol, the organic solvent may be ethyl glycol, 1-propanol, tetrahydraulic franc, 4-hydroxyl, 4-methyl, 2-pentanone, 1-butanol, 2-butanol, methanol, ethanol, n-propyl alcohol, dimethylether, and the like. According to the exemplary embodiment, the processing fluid may be carbon dioxide. The first nozzle 462, the second nozzle 464, and the third nozzle 466 are supported on different arms 461, and the arms 461 may be moved independently. Optionally, the first nozzle 462, the second nozzle 464, and the third nozzle 466 may be mounted on the same arm and moved simultaneously.

The lifting unit 480 may move the cup 420 in an up and down direction. By moving the cup 420 up and down, the relative height between the cup 420 and the substrate W may change. Through this, the recovery containers 422, 424, and 426 to which pre-processing liquids are recovered are changed according to the type of liquid supplied to the substrate W, so that it is possible to separate and recover the liquids. Unlike the description, the cup 420 may be fixedly installed, and the lifting unit 480 may move the support unit 440 in the vertical direction.

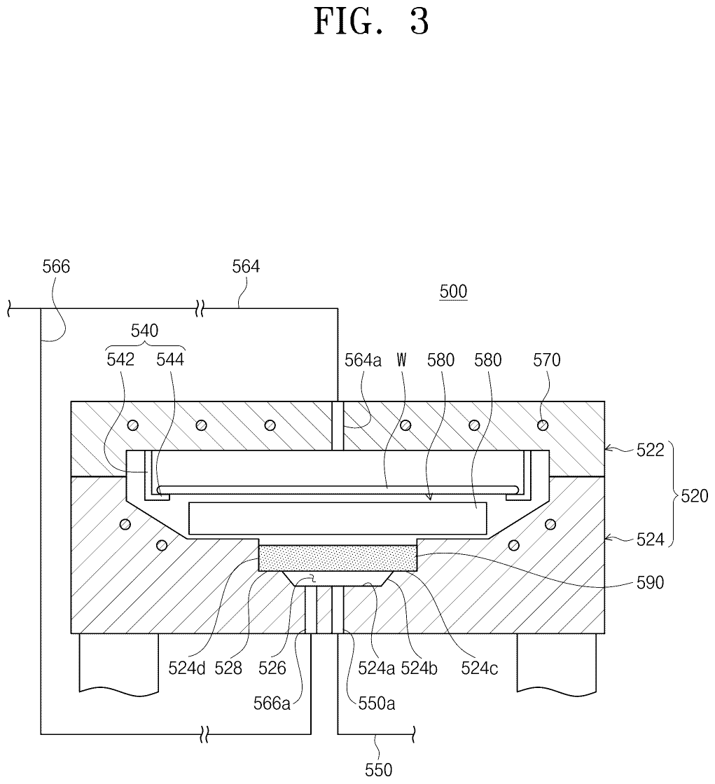

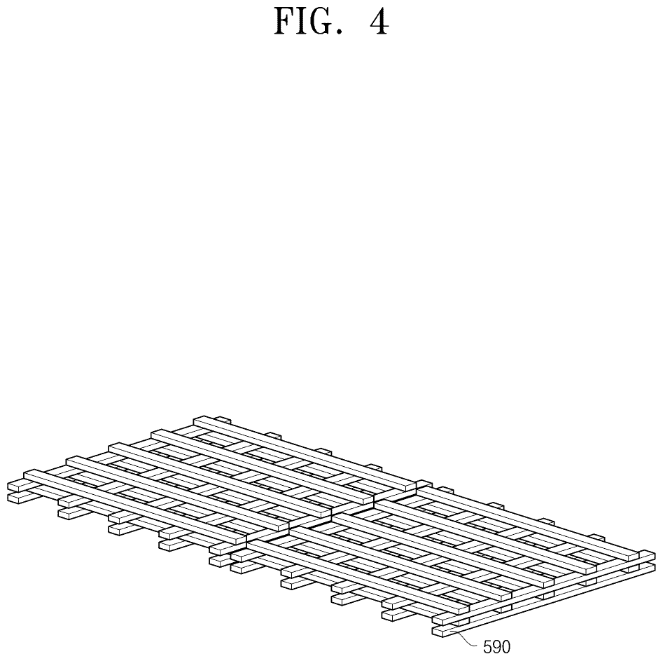

FIG. 3 is a top plan view schematically illustrating a first exemplary embodiment of a drying chamber provided in the substrate treating apparatus according to the exemplary embodiment of the present invention. FIG. 4 is a perspective view schematically illustrating a porous member according to the exemplary embodiment of the present invention.

Referring to FIGS. 3 and 4, the drying chamber 500 may dry process the substrate W by supplying a processing fluid to the substrate W that has been liquid processed in the liquid treating chamber 400. The processing fluid may be a supercritical fluid. According to the exemplary embodiment, the drying chamber 500 may remove the liquid on the substrate W by using a supercritical fluid, which may be carbon dioxide in a supercritical state.

The drying chamber 500 may include a housing 520, a support unit 540, a fluid supply unit 560, a heater 570, a filler unit 580, and a porous member 590.

The housing 520 may provide a processing space 502 where the drying process is performed. The housing 520 may have an upper body 522 and a lower body 524, and the upper body 522 and the lower body 524 may be combined with each other to provide the processing space 502 described above. The upper body 522 may be provided on top of the lower body 524. The upper body 522 may be fixed in position, and the lower body 524 may be raised and lowered by a drive member (not illustrated), such as a cylinder. When the lower body 524 is spaced apart from the upper body 522, the processing space 502 may be opened, and in this case, the substrate W may be loaded or unloaded. In process, the lower body 524 may be in close contact with the upper body 522 so that the processing space 502 may be sealed from the outside.

A bottom wall of the lower body 524 may have a center groove 526 formed therein, defined by a first bottom surface 524a of the lower body 524 and a first inner surface 524b of the lower body 524. A buffer groove 528 may be formed in the bottom wall of the lower body 524, positioned above the center groove 526, and defined by a second bottom surface 524c of the lower body 524 and a second inner surface 524d of the lower body 524.

The support unit 540 may support the substrate W within the processing space 502 of the housing 520. The support unit 540 may include a fixing rod 542 and a cradle 544.

The fixing rod 542 may be fixedly installed on the upper body 522 such that the fixing rod 542 protrudes downwardly from a bottom surface of the upper body 522. A longitudinal direction of the fixing rod 542 may be provided in the up and down direction. The fixing rods 542 may be provided in plurality and may be spaced apart from each other. The fixing rods 542 may be arranged such that when the substrate W is loaded into or unloaded from the space enclosed thereby, the substrate W does not interfere with the fixing rods 542. Each of the fixing rods 542 may be coupled to the cradle 544.

The cradle 544 may extend from the lower ends of the fixing rods 542 in a direction toward the space surrounded by the fixing rods 542. Due to the above-described structure, the substrate W loaded into the processing space 502 of the housing 520 may have an edge region thereof placed on the cradle 544, and an entire top surface region of the substrate W, a center region of the bottom surface of the substrate W, and a portion of the edge region of the bottom surface of the substrate W may be exposed to the processing fluid supplied to the processing space 502.

A first supply port 566a, a second supply port 564a, and an exhaust port 550a may be formed in the housing 520. The first supply port 566a and the second supply port 564a may supply the processing fluid to the interior of the housing 520.

The first supply port 566a may be provided in a center region of the bottom wall of the housing 520. The first supply port 566a may be formed in a region where the center groove 526 of the housing 520 is formed. The first supply port 566a may be provided in a center region of the first bottom surface 524a of the housing 520. The first supply port 566a may be formed at a location that penetrates the bottom wall in an up and down direction. The first supply port 566a may supply the processing fluid to a space in the processing space 502 of the housing 520 that is positioned under of the substrate W.

The second supply port 564a may be provided in the upper wall of the housing 520. The second supply port 564a may supply a processing fluid to a space in the processing space 502 of the housing 520 that is positioned above the substrate W. The processing fluid supplied from the second supply port 564a may be provided to the top surface of the substrate W.

The exhaust port 550a may exhaust the fluid residing inside the housing 520 to the outside. The exhaust port 550a may be provided on the bottom wall of the housing 520. The exhaust port 550a may be positioned adjacent to the first supply port 566a. The exhaust port 550a may be provided in a center region of the first bottom surface 524a of the housing 520. The exhaust port 550a may be provided in a region in which the center groove 526 of the housing 520 is formed. In the exemplary embodiment, the exhaust port 550a is formed at a location that penetrates the bottom wall in the up and down direction. In the exemplary embodiment, the diameter of the exhaust port 550a may be provided to be smaller than the diameter of the first supply port 566a. The fluid exhausted from the exhaust port 550a includes a processing fluid in which an organic solvent is dissolved. The fluid exhausted from the exhaust port 550a may be directed to a regeneration device (not illustrated). In the regeneration device, the fluid may be separated into a processing fluid and an organic solvent. In contrast, the fluid exhausted from the exhaust port 550a may be released to the atmosphere via an exhaust line 550.

The fluid supply unit 560 may supply a processing fluid to the processing space 502 of the housing 520. In the exemplary embodiment, the processing fluid may be supplied to the processing space 502 in a supercritical state. Alternatively, the processing fluid may be supplied to the processing space 502 in a gaseous state and be phase-changed to the supercritical state within the processing space 502. According to the exemplary embodiment, the fluid supply unit 560 may include a main supply line 562, an upper branch line 564, and a lower branch line 566. The upper branch line 564 and the lower branch line 566 may be branched from the main supply line 562. The upper branch line 564 may be coupled to the second supply port 564a to supply the processing fluid from the top of the substrate W placed on the support unit 540. The lower branch line 566 may be coupled to the first supply port 566a to supply the processing fluid from the lower portion of the substrate W placed on the support unit 540. The exhaust line 550 may be coupled to the exhaust port 550a. The fluid within the processing space 502 of the housing 520 may be exhausted to the outside of the housing 520 via the exhaust line 550.

The heater 570 may be positioned inside a wall of the housing 520. The heater 570 may heat the processing space 502 of the housing 520 such that the processing fluid supplied into the processing space 502 of the housing 520 remains in a supercritical state.

The filler unit 580 may be provided within the processing space 502 of the housing 520. The filler unit 580 may be provided in the shape of a disk. The filler unit 580 is supported by a support (not illustrated) to be spaced upwardly from the second bottom surface 52 of the lower body 524. The supports may be provided in the form of rods, and may be arranged in plurality to be spaced apart from each other by a certain distance. When viewed from above, the filler unit 580 may be provided to overlap an outlet of the lower branch line 566 and an inlet of the exhaust line 550.

The porous member 590 may be provided within the processing space 502 of the housing 520. The porous member 590 may have porosity. The porous member 590 may be provided from a porous material. The porous member 590 may be plate-shaped. The porous member 590 may be disposed to face the first supply port 566a. In the exemplary embodiment, the porous member 590 may be disposed to face the exhaust port 550a.

The porous member 590 may be provided below the substrate W supported by the support unit 540. The porous member 590 may be disposed spaced apart from the bottom wall of the lower body 524 at a position higher than the bottom wall of the lower body 524. The porous members 590 may be disposed opposite the filler unit 580. When viewed from above, the porous member 590 may be provided with a smaller area than the filler unit 580.

The porous member 590 may be disposed within the buffer groove 528. The porous member 590 may be in contact with a bottom surface of the surfaces defining the buffer groove 528. The bottom surface of the surfaces defining the buffer groove 528 may be the second bottom surface 524c. In the exemplary embodiment, when viewed from above, the porous member 590 may be provided with the same area as the buffer groove 528.

The processing fluid supplied through the first supply port 566a may have a reduced velocity of airflow as it passes through the porous member 590. Turbulence may be formed on the underside of the substrate W or the underside of the filler unit 580 by the processing fluid passing through the porous member 590. Thus, turbulence formed at the edge region of the substrate W may be minimized.

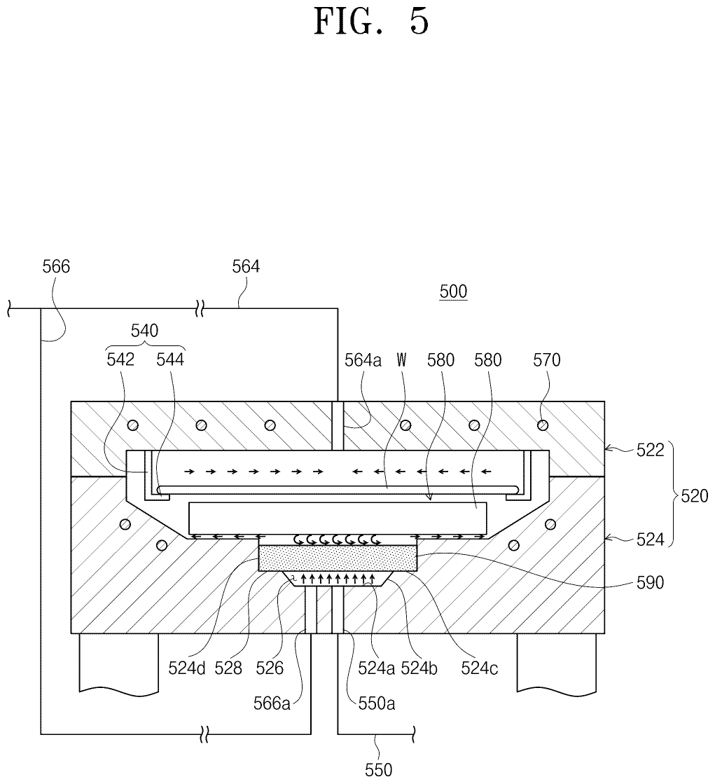

FIG. 5 is a diagram schematically illustrating a flow of the processing fluid when the processing fluid is supplied to the drying chamber according to the exemplary embodiment of the present invention.

Referring to FIG. 5, the processing fluid introduced into the interior of the housing 520 through the first supply port 566a may have a reduced velocity as it passes through the porous member 590, and turbulence of the processing fluid may form between the filler unit 580 and the porous member 590. As a result, vortices caused by the processing fluid may not be generated at the edge of the substrate W, and the flow of the processing fluid on the substrate W may be uniformly controlled.

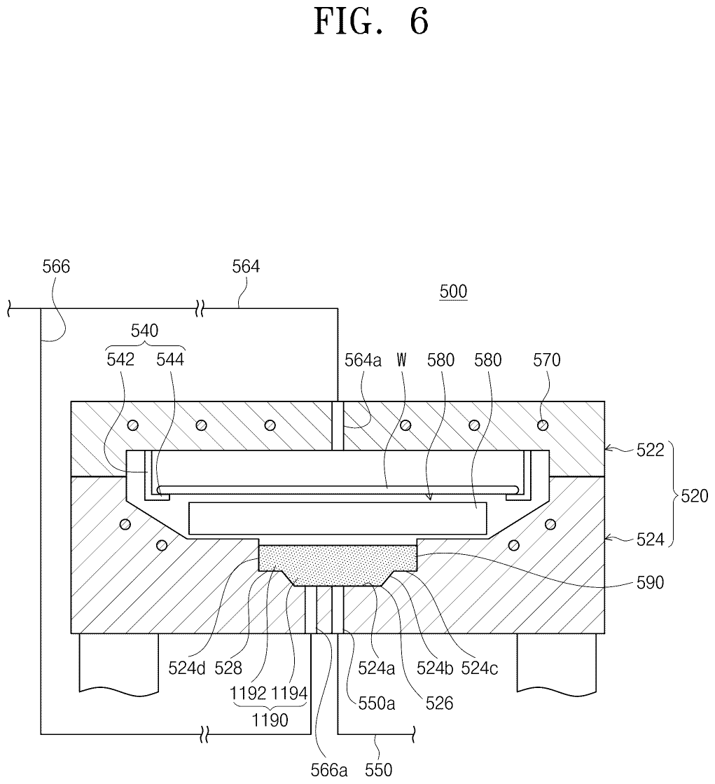

FIG. 6 is a top plan view schematically illustrating a second exemplary embodiment of a drying chamber provided in the substrate treating apparatus according to the exemplary embodiment of the present invention.

Referring to FIG. 6, a drying chamber 1100 according to a second exemplary embodiment of the present invention may include a housing 520, a support unit 540, a fluid supply unit 560, a heater 570, a filler unit 580, and a porous member 1190.

The porous member 1190 may include porosity. The porous member 1190 may be provided from a porous material. The porous member 1190 may include a first porous member 1192 and a second porous member 1194.

The first porous member 1192 may be provided in the buffer groove 528. The first porous member 1192 may be plate-shaped, and may be the same as the porous member 590 described in FIGS. 3 and 4.

The second porous member 1194 may be provided in the center groove 526. The second porous member 1194 may be formed by extending downwardly from the first porous member 1192. The cross-sectional area of the second porous member 1194 may decrease downwardly. The second porous member 1194 may be disposed to face the first supply port 566a. In the exemplary embodiment, the second porous member 1194 may be disposed to face the exhaust port 550a.

The second porous member 590 may contact a bottom surface of the surfaces defining the center groove 526. The bottom surface of the surfaces defining the center groove 526 may be the first bottom surface 524a.

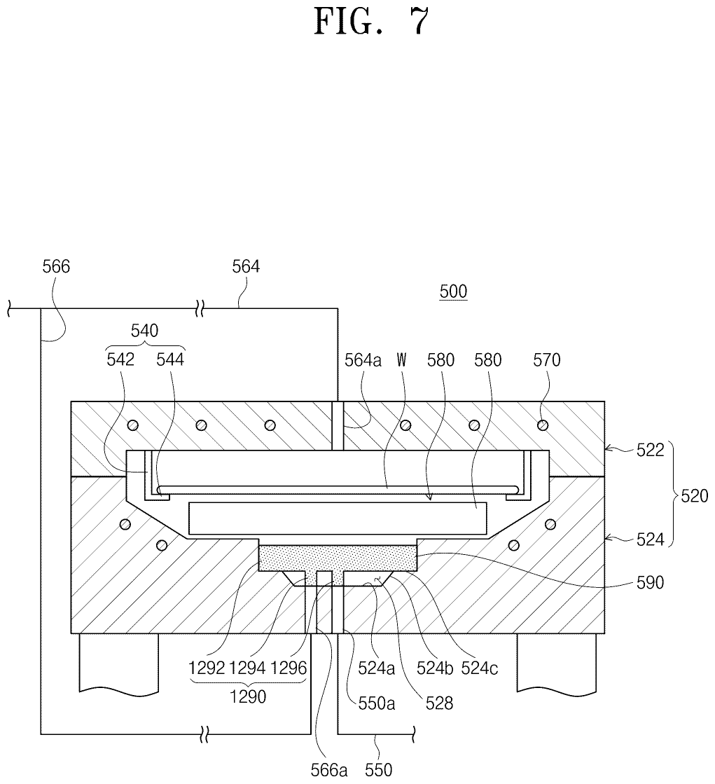

FIG. 7 is a top plan view schematically illustrating a third exemplary embodiment of a drying chamber provided in the substrate treating apparatus according to the exemplary embodiment of the present invention.

Referring to FIG. 7, a drying chamber 1200 according to a third exemplary embodiment of the present invention may include a housing 520, a support unit 540, a fluid supply unit 560, a heater 570, a filler unit 580, and a porous member 1290.

The porous member 1290 may include porosity. The porous member 1290 may be provided from a porous material. The porous member 1290 may include a plate part 1292, a first leg part 1294, and a second leg part 1296.

A plate part 1292 may be provided in the buffer groove 528. The plate part 1292 may be the same as the porous member 590 described in FIGS. 3 and 4.

The first leg part 1294 may be provided in the center groove 526. The first leg part 1294 may be formed by extending downwardly from the plate part. In the exemplary embodiment, the first leg part 1294 may be cylindrical in shape. The first leg part 1294 may contact the first supply port 566a. When viewed from above, the first leg part 1294 may be provided with a wider area than the outlet of the first supply port 566a.

The second leg part 1296 may be provided in the center recess 526. The second leg part 1296 may be formed by extending downwardly from the plate part. In the exemplary embodiment, the first leg part 1294 may be cylindrical in shape. The second leg part 1296 may contact the exhaust port 550a. When viewed from above, the second leg part 1296 may be provided with a larger area than the inlet of the exhaust port 550a.

The above detailed description is illustrative of the present invention. In addition, the foregoing is intended to describe exemplary or various exemplary embodiments for implementing the technical spirit of the present invention, and the present invention may be used in various other combinations, changes, and environments. That is, the foregoing content may be modified or corrected within the scope of the concept of the invention disclosed in the present specification, the scope equivalent to that of the invention, and/or the scope of the skill or knowledge in the art. Accordingly, the detailed description of the invention above is not intended to limit the invention to the disclosed exemplary embodiment. Further, the appended claims may be construed to include other exemplary embodiments. Such modified exemplary embodiments should not be separately understood from the technical spirit or prospects of the present invention.

What is claimed is:

1. An apparatus for processing a substrate, the apparatus comprising:
a housing providing a processing space;
a support unit for supporting a substrate in the processing space;
a first supply port for supplying a processing fluid into the processing space;
an exhaust port for exhausting the processing fluid within the processing space; and
a porous member disposed to face the first supply port within the processing space, and having pores.

2. The apparatus of claim 1, wherein the porous member is provided in a porous material.

3. The apparatus of claim 1, wherein the porous member is provided below the substrate supported on the support unit.

4. The apparatus of claim 1, wherein a buffer groove is formed in a bottom wall of the housing, and
the porous member is disposed within the buffer groove.

5. The apparatus of claim 4, wherein when viewed from above, the porous member is provided with the same area as the buffer groove.

6. The apparatus of claim 4, wherein the porous member is provided to be in contact with a bottom surface of surfaces defining the buffer groove.

7. The apparatus of claim 4, wherein the bottom wall is further formed with a center groove extending from the buffer groove and positioned below the buffer groove, and
the first supply port is provided on a bottom surface of surfaces forming the center groove.

8. The apparatus of claim 7, wherein the porous member is provided only in the buffer groove between the buffer groove and the center groove.

9. The apparatus of claim 4, wherein the porous member is spaced apart from the bottom wall at a position higher than the bottom wall.

10. The apparatus of claim 1, wherein a filler member is provided between the porous member and the substrate supported on the support unit.

11. The apparatus of claim 10, wherein the porous member and the filler member are disposed opposite each other.

12. The apparatus of claim 10, wherein when viewed from above, the filler member is provided with a larger area than the porous member.

13. The apparatus of claim 1, further comprising:
a second supply port formed above the substrate supported on the support unit, and for supplying a processing fluid to the processing space.

14. An apparatus for treating a substrate, the apparatus comprising:
a housing providing a processing space;
a support unit for supporting a substrate in the processing space;
a supply port for supplying a processing fluid into the processing space;
an exhaust port for exhausting the processing fluid within the processing space; and
a porous member disposed to face the supply port and the exhaust port within the processing space, and having pores,
wherein the porous member includes:
a plate part having a plate shape;
a first leg part extending downwardly from the plate part and being in contact with the supply port; and
a second leg part extending downwardly from the plate part and being in contact with the exhaust port.

15. The apparatus of claim 14, wherein the first leg part and the second leg part have a cylindrical shape.

16. The apparatus of claim 15, wherein when viewed from above, the first leg part is provided with a wider area than an outlet of the supply port, and
the second leg part is provided with an area wider than an inlet of the exhaust port.

17. An apparatus for treating a substrate, the apparatus comprising:
a housing providing a processing space;
a support unit for supporting a substrate in the processing space;
a first supply port for supplying a processing fluid into the processing space;
an exhaust port for exhausting the processing fluid within the processing space;
a second supply port formed above the substrate supported on the support unit, and for supplying a processing fluid to the processing space;
a buffer groove formed in a bottom wall of the housing;
a porous member disposed within the buffer groove; and
a filler member provided between the porous member and the substrate supported on the support unit, and
the porous member is provided from a porous material.

18. The apparatus of claim 17, wherein the porous member is provided below the substrate supported on the support unit, and
the porous member is provided with the same area as the buffer groove when viewed from above, and
the porous member is provided to be in contact with a lower surface of surfaces defining the buffer groove.

19. The apparatus of claim 17, wherein the bottom wall is further formed with a center groove extending from the buffer groove and positioned below the buffer groove, and
the first supply port is provided on a bottom surface of surfaces forming the center groove, and
the porous member is provided only in the buffer groove between the buffer groove and the center groove.

20. The apparatus of claim 17, wherein the porous member includes:
a plate part having a plate shape;
a first leg part extending downwardly from the plate part and being in contact with the supply port; and
a second leg part extending downwardly from the plate part and being in contact with the exhaust port, and
the first leg part and the second leg part have a cylindrical shape,
when viewed from above, the first leg part is provided with a wider area than an outlet of the supply port, and
the second leg part is provided with an area wider than an inlet of the exhaust port.
